(19) United States
(12) Patent Application Publication
(10) Pub. No.: US 2026/0135533 A1
(43) Pub. Date: May 14, 2026

(54) POWER AMPLIFIER

(71) Applicant: WAVEPIA CO., LTD., Gyeonggi-do (KR)

(72) Inventors: Sang-Hun LEE, Gyeonggi-do (KR); Sang-Yeol LEE, Gyeonggi-do (KR)

(21) Appl. No.: 19/170,261

(22) Filed: Apr. 4, 2025

(30) Foreign Application Priority Data
Nov. 11, 2024 (KR) 10-2024-0159604

(51) Int. Cl. H03G 3/30; H03F 3/45

(52) U.S. Cl. CPC H03G 3/3042; H03F 3/45179; H03G 2201/103

(57) ABSTRACT

A power amplifier includes: a first differential amplification unit having a 11th gain amplification unit that amplifies a gain of an input positive power signal, a 11th wideband filter that feeds back a signal in a band of 8 to 16 GHz from the positive power signal to the 11th gain amplification unit, a 12nd gain amplification unit that amplifies a gain of an input negative power signal, and a 12nd wideband filter that feeds back a signal in a band of 8 to 16 GHz from the negative power signal to the 12nd gain amplification unit; a transmission unit that transmits the positive power signal to a subsequent stage; a second differential amplification unit, a 21st wideband filter, a 22nd power amplification unit, and a 22nd wideband filter; and an output unit that integrates a positive power signal.

### BACKGROUND

The present disclosure relates to a power amplifier, and more particularly, to a power amplifier that feeds back a differential power signal through a wideband filter, amplifies the fed back signal in two stages of gain amplification and power amplification, and integrates the amplified signals into one to output, thereby stably operating in a band of 8 to 16 GHz.

In general, beamforming techniques have been widely used in various applications such as radar systems, mobile electronic devices, and satellite communications due to their superior capabilities to automatically control signal directivity compared to conventional mechanical approaches.

Recently, the powerful integration capabilities of silicon process technologies have helped to significantly reduce production costs compared to the use of individual components while maintaining the same or better quality, which leads to a lot of research focused on beamforming techniques in X-band and Q-band applications.

However, power amplifiers are essential for X-band and Q-band beamforming circuits to perform a stable operation, but conventional power amplifiers have difficulty in designing to have immunity to noise in a band of 8 to 16 GHz band.

(Patent Document 1) Korean Patent Publication No. 10-2024-00109402 (published on Jul. 11, 2024)

### SUMMARY OF THE INVENTION

An aspect of the present disclosure is to provide a power amplifier that feeds back a differential power signal through a wideband filter, amplifies the fed back signal in two stages of gain amplification and power amplification, and integrates the amplified signals into one to output, thereby stably operating in a band of 8 to 16 GHz.

Technical problems to be solved in the present disclosure may not be limited to the above-described problems and other problems, which are not mentioned herein, will definitely be understood by those skilled in the art from the following description.

In order to achieve the foregoing objectives, a power amplifier according to one embodiment of the present disclosure may include a first differential amplification unit 1100 including a 11th gain amplification unit 1211 that amplifies a gain of an input positive power signal PA_IP, a 11th wideband filter 1111 that feeds back a signal in a band of 8 to 16 GHz from the positive power signal PA_IP to the 11th gain amplification unit 1211, a 12nd gain amplification unit 1212 that amplifies a gain of an input negative power signal PA_IN, and a 12nd wideband filter 1112 that feeds back a signal in a band of 8 to 16 GHz from the negative power signal PA_IN to the 12nd gain amplification unit 1212, a transmission unit 1300 that transmits the positive power signal PA_IP amplified by the 11th gain amplification unit 1211 and the negative power signal PA_IN amplified by the 12nd gain amplification unit 1212 to a subsequent stage, a second differential amplification unit 2200 including a 21st power amplification unit 2221 that amplifies power of the amplified positive power signal PA_IP, a 21st wideband filter 2121 that feeds back a signal in a band of 8 to 16 GHz from the positive power signal PA_IP to the 21st power amplification unit 2221, a 22nd power amplification unit 2222 that amplifies power of the amplified negative power signal PA_IN, and a 22nd wideband filter 2122 that feeds back a signal in a band of 8 to 16 GHz from the negative power signal PA_IN to the 22nd power amplification unit 2222, and an output unit 2400 that integrates a positive power signal PA_IP amplified by the 21st power amplification unit 2221 and a negative power signal PA_IN amplified by the 22nd power amplification unit 2222 into one to output.

Preferably, the 11th wideband filter 1111 or the 12nd wideband filter 1112 may be configured with a resistor and a capacitor.

Preferably, the 21st wideband filter 2121 or the 22nd wideband filter 2122 may be configured with a resistor and a capacitor.

Preferably, the 11th gain amplification unit 1211 may be configured by connecting a first MOS transistor and a third MOS transistor in series, the positive power signal PA_IP may be transmitted to a gate of the first MOS transistor, a gate driving voltage may be applied to a gate of the third MOS transistor to turn it on, and a 11th bypass capacitor may be disposed between the gate of the third MOS transistor and the ground.

Preferably, the 12nd gain amplification unit 1212 may be configured by connecting a second MOS transistor and a fourth MOS transistor in series, the negative power signal PA_IN may be transmitted to a gate of the second MOS transistor, the gate driving voltage may be applied to a gate of the fourth MOS transistor to turn it on, and a 12nd bypass capacitor may be disposed between the gate of the fourth MOS transistor and the ground.

Preferably, the transmission unit 1300 may remove a DC component from the amplified positive power signal PA_IP by passing through a capacitor and transmit it to the 21st power amplification unit 2221, and remove a DC component from the amplified negative power signal PA_IN by passing through a capacitor and transmit it to the 22nd power amplification unit 2222.

Preferably, the 21st power amplification unit 2221 may be configured by connecting a fifth MOS transistor and a seventh MOS transistor in series, the positive power signal PA_IP may be transmitted to a gate of the fifth MOS transistor, a gate driving voltage may be applied to a gate of the seventh MOS transistor to turn it on, and a 21st bypass capacitor may be disposed between the gate of the seventh MOS transistor and the ground.

Preferably, the 22nd power amplification unit 2222 may be configured by connecting a sixth MOS transistor and an eighth MOS transistor in series, the negative power signal PA_IN may be transmitted to a gate of the sixth MOS transistor, the gate driving voltage may be applied to a gate of the eighth MOS transistor to turn it on, and a 22nd bypass capacitor may be disposed between the gate of the eighth MOS transistor and the ground.

Preferably, the output unit 2400 may integrate the amplified positive power signal PA_IP and the amplified negative power signal PA_IN into one and pass it through a transformer to output.

A power amplifier according to embodiments of the present disclosure may feed back a differential power signal through a wideband filter, amplify the fed back signal in two stages of gain amplification and power amplification, and integrate the amplified signals into one to output, thereby stably operating in a band of 8 to 16 GHz.

### BRIEF DESCRIPTION OF THE DRAWINGS

FIG. 1 is a circuit diagram of a power amplifier according to one embodiment of the present disclosure.

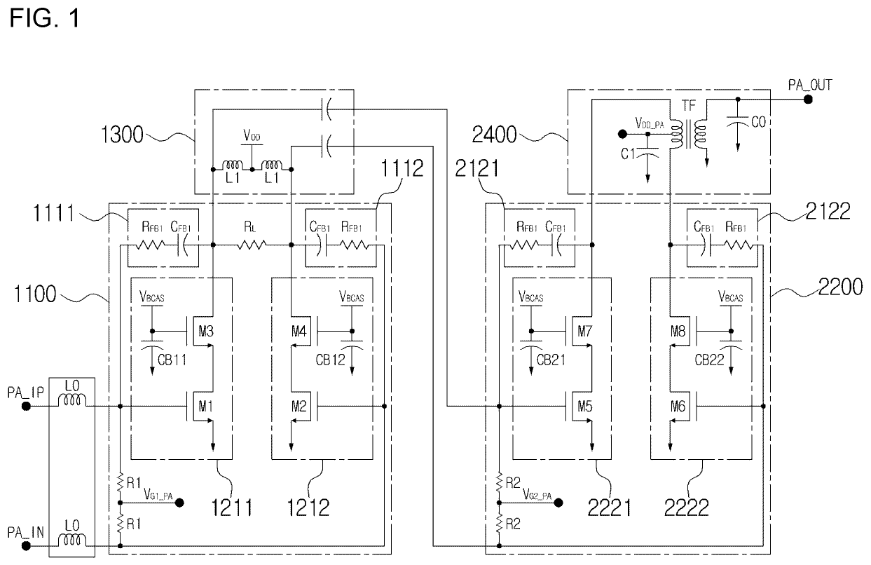

### DETAILED DESCRIPTION OF THE PREFERRED EMBODIMENT

The detailed description of the present disclosure described below refers to the accompanying drawings, which show, by way of illustration, specific embodiments to carry out the present disclosure. These embodiments are described in sufficient detail to enable those skilled in the art to carry out the present disclosure. It should be understood that various embodiments of the present disclosure are different from one another but are not necessarily mutually exclusive.

For example, specific shapes, structures and characteristics described herein may be implemented in other embodiments without departing from the concept and scope of the present disclosure in connection with one embodiment. In addition, it should be understood that the locations or arrangement of individual elements within each disclosed embodiment may be changed without departing from the concept and scope of the present disclosure.

Therefore, the following detailed description is not to be taken in a limiting sense, and the scope of the present disclosure is defined only by the appended claims along with the entire scope of equivalents thereof, if properly described.

Hereinafter, with reference to the accompanying drawings, a power amplifier according to embodiments of the present disclosure will be described.

A power amplifier according to one embodiment of the present disclosure may include a first differential amplification unit 1100 including a 11th gain amplification unit 1211 that amplifies a gain of an input positive power signal PA_IP, a 11th wideband filter 1111 that feeds back a signal in a band of 8 to 16 GHz from the positive power signal PA_IP to the 11th gain amplification unit 1211, a 12nd gain amplification unit 1212 that amplifies a gain of an input negative power signal PA_IN, and a 12nd wideband filter 1112 that feeds back a signal in a band of 8 to 16 GHz from the negative power signal PA_IN to the 12nd gain amplification unit 1212, a transmission unit 1300 that transmits the positive power signal PA_IP amplified by the 11th gain amplification unit 1211 and the negative power signal PA_IN amplified by the 12nd gain amplification unit 1212 to a subsequent stage, a second differential amplification unit 2200 including a 21st power amplification unit 2221 that amplifies power of the amplified positive power signal PA_IP, a 21st wideband filter 2121 that feeds back a signal in a band of 8 to 16 GHz from the positive power signal PA_IP to the 21st power amplification unit 2221, a 22nd power amplification unit 2222 that amplifies power of the amplified negative power signal PA_IN, and a 22nd wideband filter 2122 that feeds back a signal in a band of 8 to 16 GHz from the negative power signal PA_IN to the 22nd power amplification unit 2222, and an output unit 2400 that integrates a positive power signal PA_IP amplified by the 21st power amplification unit 2221 and a negative power signal PA_IN amplified by the 22nd power amplification unit 2222 into one to output.

Here, the 11th wideband filter 1111 or the 12nd wideband filter 1112 may be configured with a resistor RFB1 and a capacitor CFB1, and the 21st wideband filter 2121 or the 22nd wideband filter 2122 is configured with a resistor RFB2 and a capacitor CFB2.

Meanwhile, the 11th gain amplification unit 1211 may be configured by connecting a first MOS transistor M1 and a third MOS transistor M3 in series, the positive power signal PA_IP may be transmitted to a gate of the first MOS transistor M1, a gate driving voltage may be applied to a gate of the third MOS transistor M3 to turn it on, and a 11th bypass capacitor CB11 may be disposed between the gate of the third MOS transistor M3 and the ground.

In addition, the 12nd gain amplification unit 1212 may be configured by connecting a second MOS transistor M2 and a fourth MOS transistor M4 in series, the negative power signal PA_IN may be transmitted to a gate of the second MOS transistor M2, the gate driving voltage may be applied to a gate of the fourth MOS transistor M4 to turn it on, and a 12nd bypass capacitor CB12 may be disposed between the gate of the fourth MOS transistor M4 and the ground.

Here, the transmission unit 1300 may remove a DC component from the amplified positive power signal PA_IP by passing through a capacitor C1 and transmit it to the 21st power amplification unit 2221, and remove a DC component from the amplified negative power signal PA_IN by passing through a capacitor C1 and transmit it to the 22nd power amplification unit 2222.

Meanwhile, the 21st power amplification unit 2221 may be configured by connecting a fifth MOS transistor M5 and a seventh MOS transistor M7 in series, the positive power signal PA_IP may be transmitted to a gate of the fifth MOS transistor M5, a gate driving voltage is applied to a gate of the seventh MOS transistor M7 to turn it on, and a 21st bypass capacitor CB21 may be disposed between the gate of the seventh MOS transistor M7 and the ground.

In addition, the 22nd power amplification unit 2222 may be configured by connecting a sixth MOS transistor M6 and an eighth MOS transistor M8 in series, the negative power signal PA_IN may be transmitted to a gate of the sixth MOS transistor M6, the gate driving voltage may be applied to a gate of the eighth MOS transistor M8 to turn it on, and a 22nd bypass capacitor CB22 is disposed between the gate of the eighth MOS transistor M8 and the ground.

Here, the output unit 2400 may integrate the amplified positive power signal PA_IP and the amplified negative power signal PA_IN into one and pass it through a transformer TF to output PA_OUT.

In the above, although the present disclosure has been described and shown with reference to preferred embodiments for illustrating the principles of the present disclosure, the present disclosure is not limited to the exact construction and operation shown and described.

Rather, those skilled in the art will readily appreciate that many changes and modifications to the present disclosure can be made without departing from the concept and scope of the appended claims.

Accordingly, all such appropriate changes, modifications, and equivalents should also be considered to fall within the scope of the present disclosure.

What is claimed is:

1. A power amplifier comprising:
a first differential amplification unit comprising a 11th gain amplification unit that amplifies a gain of an input positive power signal, a 11th wideband filter that feeds back a signal in a band of 8 to 16 GHz from the positive power signal to the 11th gain amplification unit, a 12nd gain amplification unit that amplifies a gain of an input negative power signal, and a 12nd wideband filter that feeds back a signal in a band of 8 to 16 GHz from the negative power signal to the 12nd gain amplification unit;
a transmission unit that transmits the positive power signal amplified by the 11th gain amplification unit and the negative power signal amplified by the 12nd gain amplification unit to a subsequent stage;
a second differential amplification unit comprising a 21st power amplification unit that amplifies power of the amplified positive power signal, a 21st wideband filter that feeds back a signal in a band of 8 to 16 GHz from the positive power signal to the 21st power amplification unit, a 22nd power amplification unit that amplifies power of the amplified negative power signal, and a 22nd wideband filter that feeds back a signal in a band of 8 to 16 GHz from the negative power signal to the 22nd power amplification unit; and
an output unit that integrates a positive power signal amplified by the 21st power amplification unit and a negative power signal amplified by the 22nd power amplification unit into one to output.

2. The power amplifier of claim 1, wherein the 11th wideband filter or the 12nd wideband filter is configured with a resistor and a capacitor.

3. The power amplifier of claim 2, wherein the 21st wideband filter or the 22nd wideband filter is configured with a resistor and a capacitor.

4. The power amplifier of claim 3, wherein the 11th gain amplification unit is configured by connecting a first MOS transistor and a third MOS transistor in series, the positive power signal is transmitted to a gate of the first MOS transistor, a gate driving voltage is applied to a gate of the third MOS transistor to turn it on, and a 11th bypass capacitor is disposed between the gate of the third MOS transistor and the ground.

5. The power amplifier of claim 4, wherein the 12nd gain amplification unit is configured by connecting a second MOS transistor and a fourth MOS transistor in series, the negative power signal is transmitted to a gate of the second MOS transistor, the gate driving voltage is applied to a gate of the fourth MOS transistor to turn it on, and a 12nd bypass capacitor is disposed between the gate of the fourth MOS transistor and the ground.

6. The power amplifier of claim 5, wherein the transmission unit removes a DC component from the amplified positive power signal by passing through a capacitor and transmits it to the 21st power amplification unit, and removes a DC component from the amplified negative power signal by passing through a capacitor and transmits it to the 22nd power amplification unit.

7. The power amplifier of claim 6, wherein the 21st power amplification unit is configured by connecting a fifth MOS transistor and a seventh MOS transistor in series, the positive power signal is transmitted to a gate of the fifth MOS transistor, a gate driving voltage is applied to a gate of the seventh MOS transistor to turn it on, and a 21st bypass capacitor is disposed between the gate of the seventh MOS transistor and the ground.

8. The power amplifier of claim 7, wherein the 22nd power amplification unit is configured by connecting a sixth MOS transistor and an eighth MOS transistor in series, the negative power signal is transmitted to a gate of the sixth MOS transistor, the gate driving voltage is applied to a gate of the eighth MOS transistor to turn it on, and a 22nd bypass capacitor is disposed between the gate of the eighth MOS transistor and the ground.

9. The power amplifier of claim 8, wherein the output unit integrates the amplified positive power signal and the amplified negative power signal into one and passes it through a transformer to output.
